(19) United States
(12) Patent Application Publication
(10) Pub. No.: US 2009/0314198 A1
(43) Pub. Date: Dec. 24, 2009

(54) DEVICE AND METHOD FOR PRODUCTION OF SEMICONDUCTOR GRADE SILICON

(75) Inventors: Stein Julsrud, Skien (NO); Tyke Laurence Naas, Forsgrunn (NO)

Correspondence Address: BIRCH STEWART KOLASCH & BIRCH, PO BOX 747, FALLS CHURCH, VA, 22040-0747, US

(73) Assignee: REC ScanWafer AS, Porsgrunn (NO)

(21) Appl. No.: 12/305,908

(22) PCT Filed: Jun. 20, 2007
(86) PCT No.: PCT/NO2007/000219

§ 371 Date: Feb. 20, 2009

Related U.S. Application Data
(60) Provisional application No. 60/815,860, filed on Jun. 23, 2006.

(51) Int. Cl. C30B 15/10; C30B 11/00; C30B 15/00

(52) U.S. Cl. 117/13; 117/81; 117/208; 117/223

(57) ABSTRACT

This invention relates to a device and method for production of ingots of semiconductor grade silicon, including solar grade silicon, where the presence of oxygen in the hot zone is substantially reduced or eliminated by employing materials void of oxides in the hot zone of the melting and crystallisation process. The method may be employed for any known process including for ciystallising semiconductor grade silicon ingots, including solar grade silicon ingots, such as the Bridgman process, the block-casting process, and the CZ-process for growth of monocrystalline silicon crystals. The invention also relates to devices for carrying out the melting and crystallisation processes, where the materials of the hot zone are void of oxides.

This invention relates to a device and method for production of ingots of semiconductor grade silicon, including solar grade silicon.

### BACKGROUND

The world supplies of fossil oil are expected to be gradually exhausted in the following decades. This means that our main energy source for the last century will have to be replaced within a few decades, both to cover the present energy consumption and the coming increase in the global energy demand.

In addition, many concerns are raised that the use of fossil energy increases the earth greenhouse effect to an extent that may turn dangerous. Thus the present consumption of fossil fuels should preferably be replaced by energy sources/carriers that are renewable and sustainable for our climate and environment.

One such energy source is solar light, which irradiates the earth with vastly more energy than the present day consumption, including any foreseeable increase in human energy consumption. However, solar cell electricity has up to date been too expensive to be competitive with nuclear power, thermal power etc. This needs to change if the huge potential of the solar cell electricity is to be realised.

The cost of electricity from a solar panel is a function of the energy conversion efficiency and the production costs of the solar panel. Thus one strategy for reducing the costs of solar cell electricity is increasing the energy conversion efficiency.

### PRIOR ART

In today's photovoltaic (PV) industry multicrystalline wafers for PV applications are cut from ingots that are cast in furnaces by directional solidification (DS) based on the Bridgman method. A main challenge in these processes is to maintain the purity of the silicon raw material. Two of the elements causing contamination problems are oxygen and carbon.

According to the “Handbook of Photovoltaic Science and Engineering”, John Wiley & Sons, 2003, there is a problem in that oxides or oxide containing materials in contact with the molten metal (including migration through the release coating) introduce oxygen in the molten metal. The oxygen leads to formation of SiO gas evaporating from the melt, and the SiO gas will subsequently react with graphite in the hot zone forming CO gas. The CO gas enters the silicon melt and thus introduces carbon into the solid silicon. That is, the use of oxide or oxide-containing materials in the hot zone may cause a sequence of reactions leading to introduction of both carbon and oxygen in the solid silicon. Typical values associated with the Bridgman method is interstitial oxygen levels of 2-6·10¹⁷/cm² and 2-6·10¹⁷/cm² of substitutional carbon.

Build-up of carbon in the silicon metal may lead to formation of needle shaped SiC crystals, especially in the uppermost region of the ingot. These needle shaped SiC crystals are known to short-cut pn-junctions of the semiconductor cell, leading to drastically reduced cell efficiencies. Build up of interstitial oxygen may lead to oxygen precipitates and/or recombination active oxygen complexes after annealing of the formed silicon metal.

### OBJECTIVE OF THE INVENTION

The main objective of the invention is to provide a production method of high-purity ingots of semiconductor grade silicon which substantially reduces/eliminates the problem of carbon and oxygen contamination of the silicon metal.

A further objective of the invention is to provide a device for performing the inventive method.

The objective of the invention may be realised by the features as set forth in the description of the invention below, and/or in the appended patent claims.

### DESCRIPTION OF THE INVENTION

The invention is based on the realisation that the problem with carbon and/or oxygen contamination of the silicon is coupled to presence of oxide or oxide-containing materials in the hot reducing environment of the furnaces, and that the presently used materials in the hot zone, such as electrical insulation, crucibles, load carrying building elements and thermal insulation may be replaced by materials void of oxides.

Thus in a first aspect of the invention there is provided a method for production of semiconductor grade silicon ingots, where the presence of oxygen in the hot zone is substantially reduced or eliminated by

crystallizing the semiconductor grade silicon ingot, optionally also including the melting of the feed silicon material, in a crucible made of silicon nitride, silicon carbide, or a composite of these, optionally coated with a oxide free release coating,

containing the crucible in a sealed hot zone with an inert atmosphere during crystallisation of the ingot, optionally also including the melting of the feed silicon material,

employing load carrying building elements including heat insulation elements in at least the hot zone which are made of carbon and/or graphite materials, and

employing electric insulating elements in at least the hot zone which are made of silicon nitride, Si₃N₄.

The method according to the first aspect of the invention may be employed for any known process including for crystallising semiconductor grade silicon ingots, including solar grade silicon ingots, such as the Bridgman process or related direct solidification methods, the block-casting process, and the CZ-process for growth of monocrystalline silicon crystals.

In a second aspect of the invention there is provided a device for manufacturing ingots of semiconductor grade silicon, monocrystalline or multicrystalline, comprising a sealed hot zone with an inert atmosphere, where

all load carrying building elements of the device including heat insulation elements in at least the hot zone are made of carbon and/or graphite materials,

the electric insulation in at least the hot zone is made of silicon nitride, Si₃N₄, and

the crucible is made of either silicon nitride (Si₃N₄), silicon carbide (SiC), or a composite of these, optionally coated with a oxide free release coating

The term “inert atmosphere” as used herein means an atmosphere in contact with the materials of the device and silicon metal in the hot zone which is essentially chemically inert towards the materials of the device and the silicon metal phase, both in the solid and liquid state. The term as used herein includes any gas pressure of the inert atmosphere, including vacuum.

The device may be any known device for crystallising semiconductor grade silicon ingots, including solar grade silicon ingots, such as furnaces for carrying out the Bridgman process or related direct solidification processes, crystallisation pots for performing the block-casting process, CZ-pullers for performing CZ-growth of monocrystalline silicon crystals.

By using non-oxide materials in the hot zone during the melting and crystallisation of solar grade silicon, the problem with both carbon and oxygen contamination of the silicon metal phase is eliminated/substantially reduced. This will substantially reduce formation of silicon carbide crystals in the metal phase, promoting high solar conversion efficiency of the PV cell made from the wafer. Another factor leading to higher conversion efficiencies is the reduction/avoidance of interstitial recombination-active oxygen complexes. The reduced contamination levels will also give advantages in that the subsequent processing of the silicon metal into solar wafers may be simplified due to absence of hard and brittle inclusions, such as carbides and oxides.

### LIST OF FIGURES

FIG. 1 is a schematic view of a prior art furnace for direct solidification of semiconductor grade ingots.

### EXAMPLE OF AN EMBODIMENT OF THE INVENTION

The invention will be explained in further detail by way of an example of an embodiment of the device for production of multicrystalline silicon ingots. This example should by no means be interpreted as a limitation of the general inventive concept of avoiding carbon and oxygen contamination by avoiding use of oxygen-containing materials in the hot zone. The inventive idea may be employed for any known hot zone where semiconductor grade silicon is being made.

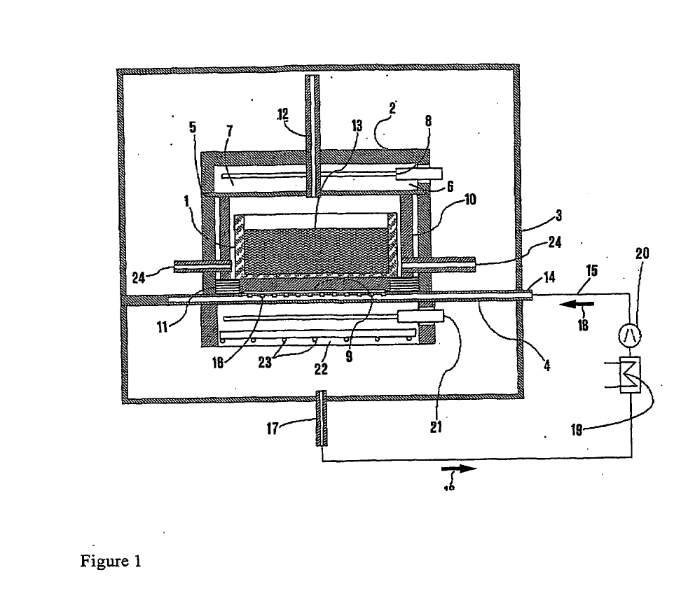

The chosen example is a typical furnace for performing directional solidification of multicrystalline silicon, as shown in FIG. 1 which is a facsimile of FIG. 1 of the applicant's International patent application WO 2006/082085. The furnace comprises a gas tight crystallisation chamber defined by insulation walls marked 2 on the FIGURE. An inner chamber is defined by floor 9 with frame 11, walls 10, and lid 5. There is provided suction outlets 24 and injection lance 12 for maintaining an inert atmosphere in the inner chamber. The metal 13 is contained in crucible 1, and the metal 13 is first melted and then subject to a directional solidification by regulating the operation of heating elements 8 and 21, and cooling circuit 4, 15, 16, 17, 19, 20, 22, and 23.

The objective of the invention when applied on this furnace may be obtained by employing a crucible 1 of silicon nitride, silicon carbide, or a composite of these, optionally coated with a oxide free release coating. An example of a suitable silicon nitride crucible is disclosed in NO 317 080, which teaches that a silicon nitride with a total open porosity between 40 and 60 volume % and where at least 50% of the pores on the surface are larger than the mean diameter of the Si₃N₄-particles, does not wet liquid silicon such that the crucible will easily slip the solidified metal. However, any crucible made of only silicon nitride and which does not wet liquid silicon may be employed. A pure silicon nitride crucible contains no, or negligible amounts of oxygen/oxides. Thus the migration of oxygen from the crucible to the liquid metal is eliminated, such that interstitial oxygen levels in the solid metal and formation of SiO will be substantially reduced or eliminated. In order to eliminate all oxygen sources in the hot zone, the example of DS-furnace according to the invention employs walls 10, floor 9 with frame 11, lid 5, and lances 24 and 12 made of carbon. Thus there are no oxygen containing elements defining the inner sealed zone of the crystallization chamber, such that both the migration of oxygen into the melt and the formation of CO-gas which comes into contact with melt is practically eliminated.

1-9. (canceled)

10. Method for production of semiconductor grade silicon ingots, where the presence of oxygen in the hot zone is substantially reduced or eliminated by
crystallizing the semiconductor grade silicon ingot, optionally also including the melting of the feed silicon material, in a crucible made of silicon nitride, silicon carbide, or a composite of these,
containing the crucible in a sealed hot zone with an inert atmosphere during crystallisation of the ingot, optionally also including the melting of the feed silicon material,
employing load carrying building elements including heat insulation elements in the hot zone which are made of carbon and/or graphite materials, and
employing electric insulating elements in the hot zone which are made of silicon nitride, Si₃N₄.

11. Method according to claim 10,
where the crucible is coated with a oxide free release coating.

12. Method according to claim 10,
where the semiconductor grade crystallisation process is the Bridgman process or a related direct solidification process, the block-casting process, or the CZ-process for growth of monocrystalline silicon crystals.

13. Method according to claim 10,
where the formed silicon ingots are solar grade silicon ingots.

14. Device for manufacturing ingots of semiconductor grade silicon, comprising a hot zone with an inert atmosphere, where
all load carrying building elements of the device including heat insulation elements in the hot zone are made of carbon and/or graphite materials,
the electric insulation in the hot zone is made of silicon nitride, Si₃N₄, and
the crucible is made of either of silicon nitride, Si₃N₄, of silicon carbide, SiC, or a composite of these.

15. Device according to claim 14,
where the crucible is coated with a oxide free release coating.

16. A crystallisation furnace for the casting of ingots for multicrystalline wafer production for photovoltaic applications characterised in that all load-carrying and functional components in the hot zone are made from non-oxide materials.

17. A furnace according to claim 14, where the casting crucible is made firm silicon nitride Si₃N₄, of silicon carbide, SiC, or a composite of these.

18. A furnace according to claim 14,
where the electrical insulation is made from Si₃N₄.

19. Method according to claim 11,
where the formed silicon ingots are solar grade silicon ingots.

20. Method according to claim 12,
where the formed silicon ingots are solar grade silicon ingots.

21. A furnace according to claim 16, where the casting crucible is made from silicon nitride, Si₃N₄, of silicon carbide, SiC, or a composite of these.

22. A furnace according to claim 16,
where the electrical insulation is made from Si₃N₄.
